(19) United States
(12) Patent Application Publication
(10) Pub. No.: US 2011/0037492 A1
(43) Pub. Date: Feb. 17, 2011

(54) WAFER PROBE TEST AND INSPECTION SYSTEM

(75) Inventors: Ronald C. Seubert, Sammamish, WA (US); Geoffrey Hilton, Berkshire (GB); Rex H. Sandbach, Wiltshire (GB)

Correspondence Address: DICKE BILLIG & CZAJA, PLLC;ATTN: CHRISTOPHER MCLAUGHLIN, 100 SOUTH FIFTH STREET, SUITE 2250, MINNEAPOLIS, MN, 55402, US

(73) Assignee: Rudolph Technologies, Inc., Flanders, NJ (US)

(21) Appl. No.: 12/600,153

(22) PCT Filed: May 15, 2008
(86) PCT No.: PCT/US08/63779

§ 371 Date: Aug. 18, 2010

Related U.S. Application Data
(60) Provisional application No. 60/938,142, filed on May 15, 2007.

(51) Int. Cl. G01R 31/00; G01R 31/26

(52) U.S. Cl. 324/756.03; 324/762.01

(57) ABSTRACT

An apparatus for electrically testing a semiconductor device is herein disclosed. The apparatus includes carriers for a semiconductor device and a probe card (52) that are adapted for complementary registration with one another. The coupled carriers may be stacked or used in another high-density arrangement during electrical test or burn-in to improve test cell utilization.

### CROSS-REFERENCE TO RELATED APPLICATIONS

This is application is related to International Patent Application No. PCT/US2008/063779, filed on 15 May 2008, which claims priority from U.S. Provisional Patent Application No. 60/938,142, filed on 15 May 2007.

### TECHNICAL FIELD OF THE INVENTION

The present invention relates to the field of electrical test methods and equipment. More particularly, this invention relates to methods and systems for the high-parallelism testing and pre and post-probe inspection and analysis of semiconductor wafers.

### BACKGROUND OF THE INVENTION

In the semiconductor industry, many replicate components, or die, are created on a single silicon wafer. In order to eliminate faulty die prior to the cost intensive step of packaging, semiconductor fabricators typically perform wafer testing or sorting. One facet of wafer testing typically consists of establishing electrical connectivity between the metalized bond pads or bumps contained on each individual die and external test equipment. In this manner, the characteristics of each die's circuitry are evaluated. Wafer testing is the final step in what is considered the “front end” processing of semiconductor devices. Also relevant is the inspection and testing of the equipment employed in wafer testing process, or the “back end” inspection and testing process.

Facets of back end inspection and testing processes may utilize probe card analyzers which evaluate the characteristics and performance of probe cards, as well as wafer probe mark analyzers which evaluate the wafer testing process through characterization of the wafer probe marks made on a wafer as a result of the probing process described below. An exemplary probe card analyzer is embodied in the ProbeWoRx® 300/200 probe card analysis system from Rudolph Technologies, Inc of Flanders, N.J. An exemplary wafer probe mark analyzer is embodied in the waferWoRx® probing process analysis system from Rudolph Technologies, Inc. of Flanders, N.J.

A conventional wafer test station, or test cell, 11 such as that illustrated in FIG. 1 typically incorporates the following components: a probe card or probe array card 10 upon which is arranged an array of fine wires, formed springs or similar conductive elements known as probe pins 12; a test head 14 upon (or in) which a probe card may be structurally coupled; a signal delivery system 16 which establishes electrical contact between the probe card and test machine electronic circuits; a manipulator 18 which functions to support and move the coupled test head and probe card; a test machine, or tester 20, which is electrically coupled to the probe card 10 and able to generate, detect and measure electrical signals in a manner suitable to determine the actual performance of one or more die 8, also known as a device under test, or DUT; a prober 22 which aligns the wafer W to the probe card 10 such that the probe pins 12 make accurate contact with the wafer bonding pads 24; and a head plate 26 which serves as a docking means between the probe card/test head complex and the prober.

In the conventional wafer test cell configuration 11, a wafer W is loaded and positioned horizontally in the prober 22 and oriented with bonding pads 24 facing up. The probe card 10 is loaded or secured to a test head 14 such that it can be positioned horizontally above the wafer W with probe pins 12 facing down. A manipulator 18 of any suitable type, in one embodiment a three axis robot arm having a rotatable coupling to permit angular adjustment of the test head 14, may be used to position the probe card/test head complex to the head plate 26 of a prober 22. The prober 22 provides alignment functionality, in one embodiment by means of a prober chuck 28 which may be mounted on a three axis stage having a rotational stage for angular adjustment (not shown) and develops a positional relationship between the probe card 10 and the bonding pads 24 of the DUT 8.

Exemplary prober alignment systems and functionalities are described in U.S. Pat. Nos. 6,096,567 and 6,111,421, both of which are hereby incorporated by reference in their entirety. For example, a prober 22 may incorporate two cameras (not shown), one operable to image the probe pins 12 of the probe card 10 and one operable to image the bonding pads 24 of the DUT. Based on such image data, the prober 22 will align the probe pins 12 to the corresponding bonding pads 24. Once a first wafer W has been aligned, probers 22 usually have a step and repeat subsystem, which permits this process to be repeated for each DUT 8 or group of DUT's. In practice, a conventional test cell 11 utilizes one tester 20 controlling one or more probers 22 with each prober testing one or multiple DUTs of one wafer W at a time.

There has been a trend over the last decade to increase the parallelism of wafer testing, particularly, for dynamic and flash memory testing. This allows devices 8 with long test times to be processed more efficiently and thereby reduce cost. The current state of the art is to test a wafer W in four touches, i.e. the probe pins 12 of the probe card are brought into contact with a single wafer W four times in order to facilitate testing of each die 8 on the wafer. In the very near future, it is expected that some wafers will be able to be tested in two, and eventually one touchdown. For certain semiconductors, such as some memory devices, each ‘touchdown’ may require between 10 and 30 minutes to complete. In the memory sector, DUT 8 test time increases relative to memory density, i.e. as memory density increases so do test times.

The conventional wafer testing methods have many drawbacks. First, the long test times mean that the prober 22 indexing and alignment hardware is underutilized resulting in a poor return on investment for the probers 22 and in some instances, testers 20 as well. Second, in an effort to reduce probing test costs, the semiconductor industry has added multiple layers of complexity to the chip making process-multi-DUT probe cards 10, smaller bonding pads 24, and tighter pitches for the bonding pads 24. These changes have, in turn, resulted in higher probe forces and a related compromise between hardware accuracy and weight in probers 22. Third, test floor layouts are currently designed to allow test heads 14 to flip for access to probe cards 10. This results in the non-optimal use of floor space. Fourth, as tester complexity increases, there is a high volume of interconnects between components and a greater potential for reliability problems. Finally, because of increased complexities in the testing process, the probe cards 10 themselves are becoming the dominant element in prober/probe card economics.

What is needed in the art is an efficient process for pre-probe wafer inspection and analysis, wafer testing, and post-probe wafer inspection and analysis that utilizes a simplified and improved approach to wafer alignment and handling.

### SUMMARY OF THE INVENTION

Certain embodiments of the present invention provide an optimized wafer test cell or station that utilizes a simplified and improved approach to wafer alignment and handling while employing an integrated process for wafer testing, as well as pre and post-probe wafer inspection and analysis.

In certain embodiments, a system for wafer prealignment onto carrier plates, or wafer carriers, is provided. Once the wafer is prealigned onto a wafer carrier, further automated wafer alignment is unnecessary. The wafer carrier itself may incorporate universal mounting and alignment hardware that facilitates alignment with test equipment. The hardware at the test location also becomes more simplified. The test equipment simply incorporates mounting hardware that is complementary to, or otherwise operable to receive the wafer carrier mounting hardware. X-Y wafer indexing required for some current multiple touchdown wafer testing may be enabled through placing the wafer carrier into multiple tooling locations at the test equipment. The wafer alignment hardware may further employ wafer inspection functionality and thereby provide for pre- and post-probe inspection of the wafer. Various software modules may utilize the acquired wafer inspection data in order to provide detailed pre-probe wafer analysis, as well as post-probe wafer analysis operable to evaluate the entire wafer test process and, ultimately, process yield management.

Certain aspects of the present invention provide various benefits over conventional wafer testing methods. First, the present invention reduces hardware costs because the conventional prober is eliminated. Second, the present invention increases tester utilization because wafer lots can be broken down and shared between multiple test equipment rather than waiting in a single prober. Third, better process control is provided because wafer alignment does not depend upon individual prober performance at each test location. Fourth, according to certain aspects of the present invention a “lights-out” wafer test floor is possible. Fifth, features of the present invention anticipate the demands of future semiconductor testing, including the need to probe even smaller and more densely positioned bonding pads, by providing probing solutions that minimize fixture deflection and employ more constant probe force. Finally, aspects of the present invention provide for higher reliability through the simplification of the entire wafer test process and great error budget control.

Certain embodiments of the present invention utilize a test station, or cell. In one example the test station or cell employs (a) a wafer aligner, or wafer alignment station; (b) a wafer carrier; and (c) a plurality of test head mounting hardware. These and other components will be described in greater detail below.

### BRIEF DESCRIPTION OF THE DRAWINGS

FIG. 1 is a schematic side view illustration of an exemplary test cell of the prior art.

FIG. 2 is a schematic illustration of a wafer-prober cassette.

FIG. 3 is a schematic, side elevation of a rack for housing multiple wafer-prober cassettes.

FIG. 4 is a schematic, plan view of an embodiment of a test cell adapted for testing wafers using a wafer cassette arrangement.

FIG. 5 is a schematic, perspective view of an embodiment of a test cell adapted for testing wafers using a wafer pod arrangement.

FIG. 6 is a schematic, cut-away side view of one embodiment of a mechanism for aligning a wafer to a wafer carrier.

FIG. 7 is a plan view of one embodiment a wafer carrier.

FIG. 8 is a side view of one embodiment of a registration mechanism.

FIG. 9 is a partial plan view of an embodiment of a registration mechanism adapted for facilitating multi-touch electrical test and burn-in.

FIG. 10 is a flow chart illustrating an embodiment of a method of testing or burning-in a semiconductor device or wafer.

FIG. 11 is a schematic, side elevation of a probe card carrier according to one embodiment of the invention.

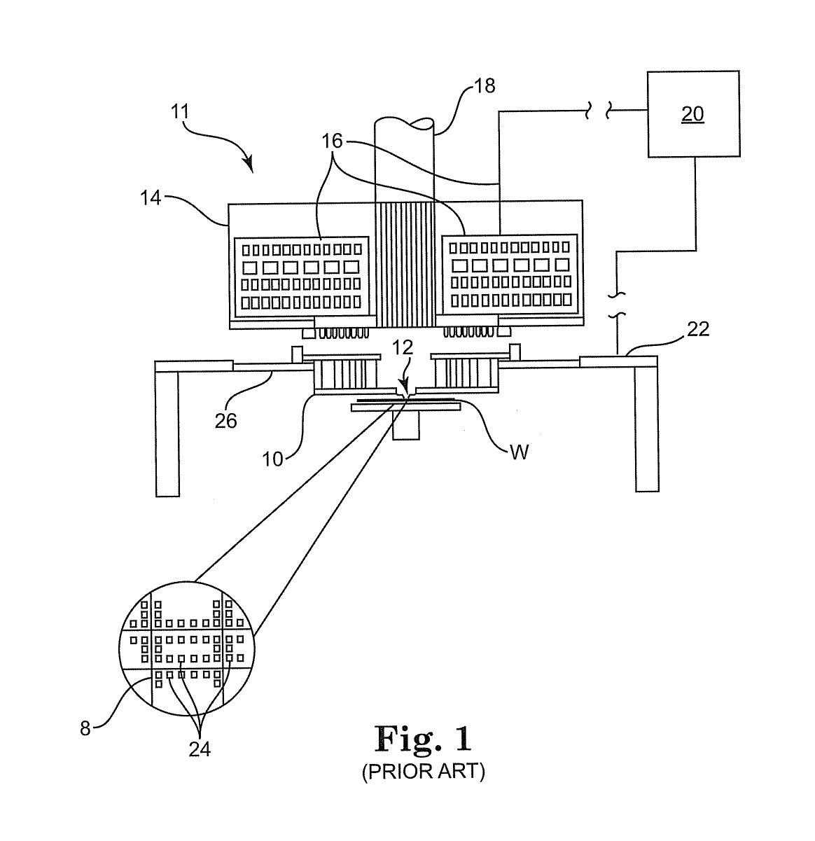

### DETAILED DESCRIPTION OF THE INVENTION

In the following detailed description of the invention, reference is made to the accompanying drawings that form a part hereof, and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention. The following detailed description is, therefore, not to be taken in a limiting sense, and the scope of the present invention is defined only by the appended claims and equivalents thereof.

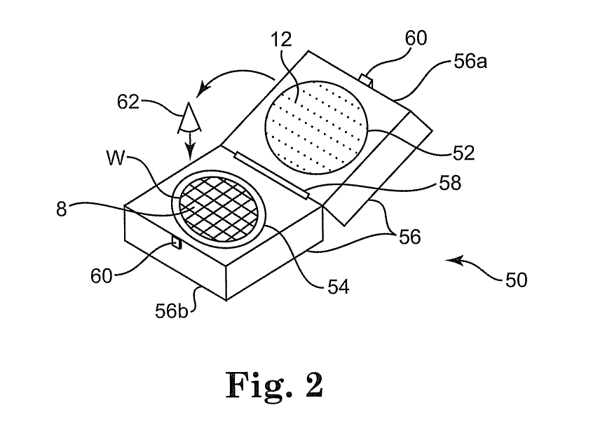

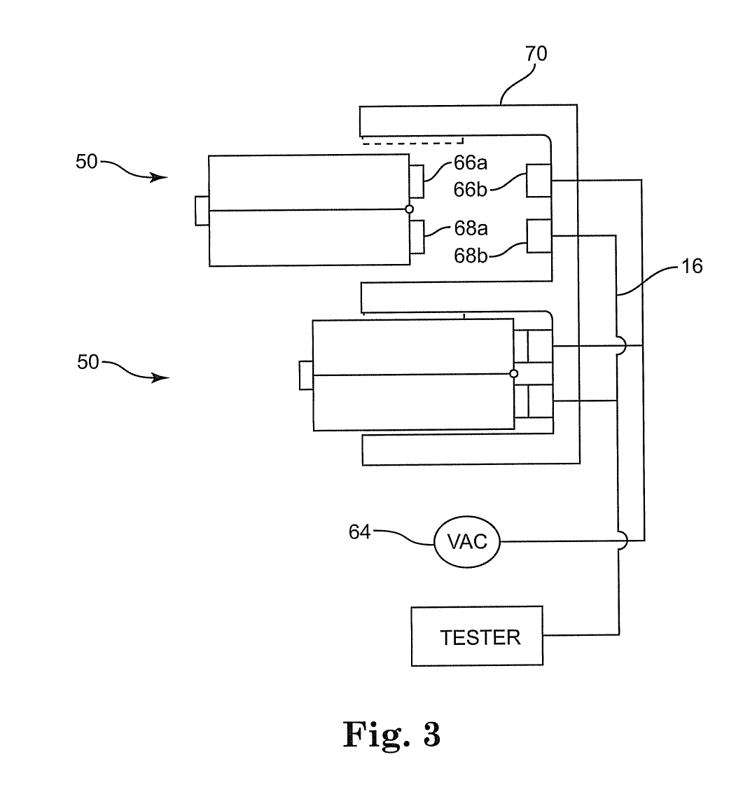

FIG. 2 illustrates an embodiment of the present invention useful for increasing utilization of a test cell. Cassette 50 includes a probe card 52 and a wafer stage 54 mounted within a housing 56. The probe card 52 is mounted to a first portion 56a of the cassette 50 and the wafer stage 54 is mounted to a second portion 56b of the cassette 50. The portions 56a and 56b of cassette 50 are in the pictured embodiment hinged together by hinge 58 such that the portions may rotate into a substantially parallel, closed position as seen in FIG. 3. Other connection and registrations means may be used in lieu of a hinge. Wafer stage 54 is provided with a retention mechanism 60 which may be a vacuum type system or a mechanical retention device, as needed. In any case, the retention mechanism retains a wafer W onto the stage 54 in a desired orientation. Use of a vacuum type retention mechanism 60 has the benefit of also conforming the wafer W to the flat surface of the stage 54. The orientation of the stage 54 may be accomplished by placing the wafer W on the stage 54 in the desired orientation or by translating the stage 54 in any of the X, Y, Z or [theta] directions or rotations with respect to the cassette 50 and more importantly, the probe card 52. To accomplish this translation, the stage 54 may be mounted on X, Y, Z or [theta] translation stages of a known type (not shown). Probe card 52 may also be mounted on X, Y, Z or [theta] translation stages (not shown) (or affixed directly to the cassette portion 56a) as required for aligning the probe pins 12 with bond pads 24 on DUT's of a wafer W.

A camera 62 may be provided to image DUT's 8 on wafer W (as seen in FIG. 2) and/or the probe card 52. Image data derived from the camera 62 may be used to calculate the requisite translations for the stage 54 and probe card 52 to align the bond pads 24 with the probe pins 12. Spatial calibration of one or more alignment cameras 62, with respect to the cassette 50 and/or to one another may allow alignment to be determined by image comparison or subtraction. Differences in the image data can therefore be converted into necessary translations of translations stages associated with the stage 54 and/or probe card 52. Feature or edge finding techniques such as Canny Edge Finding maybe used to identify features that may be used for alignment purposes, the difference between features being used to calculate the requisite translations as described above. Once alignment has been achieved, the portions of the cassette 50 may be rotated into their closed position as shown in FIG. 3 to address the probe pins 12 to the bond pads 24 to facilitate electrical testing.

Once a wafer W has been placed in a cassette 50 and the cassette closed, the closed cassette 50 may be connected to a tester 20 and to any other mechanical or electrical systems needed to perform the requisite tests as seen in FIG. 3. For example, where stage 54 is provided with a vacuum retention mechanism, the cassette 50 may be coupled to a source of vacuum 64 via couplings 66a and 66b. Similarly, signal delivery system 16 may be coupled by means of electrical couplings 68a and 68b to provide an electrical connection between the probe card 52 and the tester 20. As can also be seen in FIG. 3, multiple cassettes 50 may be coupled to a single tester 20 to raise utilization of the tester 20. In one embodiment, closed cassettes 50 having wafers W therein maybe be placed in a rack 70 of a suitable arrangement.

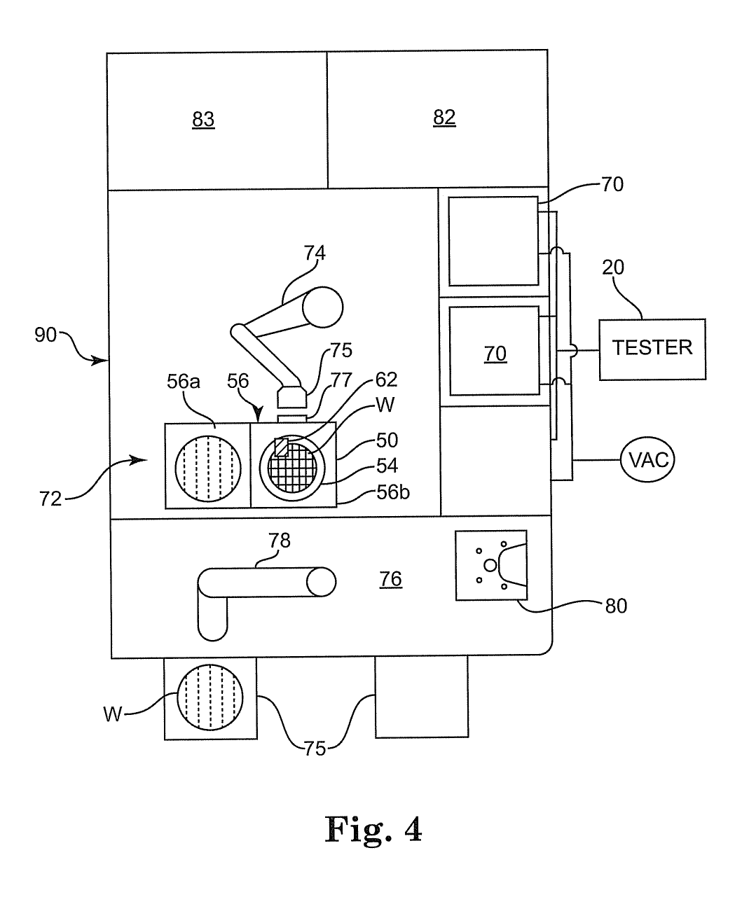

As seen in FIG. 4, a manipulator 74 which is in one embodiment a 4-axis robot arm having a suitable gripping member 75 at its distal end moves the closed cassettes 50 between one or more loading/unloading areas 72 and a rack 70 or the like. Wafers W are provided as is known from a wafer carrier or FOUP 75 to the loading/unloading area 72 by a handler 76 having a robot arm 78. Handler 76 may be provided with a pre-aligner 80 to align a wafer W before it is placed on a stage 54 of a cassette 50.

As described above, probe cards may be arranged to perform tests on wafers W in one, two, three, four or more touches. While the embodiment of cassette 50 illustrated in FIGS. 2-4 is adapted for use with a single touch probe card, i.e. the probe card 52 is sized so as to address substantially all of the bond pads on a wafer W simultaneously, it is possible to move a wafer W to multiple locations on the stage 54 to enable multi-touch testing.

In use, one embodiment of test cell 90 operates as follows. A wafer carrier with wafers W therein is coupled to one of FOUP's 75. Robot 78 of handler 76 retrieves a wafer W from the wafer carrier and moves it to the pre-aligner 80 for coarse alignment of the wafer W with respect to the components of the test cell 90. The coarse-aligned wafer W is then moved to stage 54 of a cassette 50 located in a loading/unloading station 72. If required and where so provided, a camera 62 is used in conjunction with the stage 54 to fine-align the wafer W with respect to the probe card 52 as described above. The specifications of such an alignment may vary by the application, the size of the bond pads 24 and the pitch of the bond pads 24, but is often in the range of about 5μ. Once fine-alignment has been achieved, the retention mechanism 60 of the cassette 50 is activated to hold the wafer W in its aligned position. Note that a cassette may be connected to a source of vacuum at the loading/unloading stations 72 and that vacuum is maintained in the retention mechanism 60 during transport of the closed cassette 50, in one embodiment, by means of a vacuum reservoir (not shown). Alternatively, the cassette 50 and the manipulator 74 may be provided with auxiliary vacuum couplings (not shown) to provide vacuum to the cassette during transfer through the manipulator 74. Once alignment is complete, the portions 56a,b of the cassette 50 are closed to address the probe pins 12 to the bond pads 24 of the DUTs on the wafer W. The now closed cassette 50 is then transferred to a rack 70 by the manipulator 74, which may grip the cassette 50 by a specially designed lug 77. In the rack 70, the cassette 50 is coupled, at a minimum, to the signal delivery system 16 that communications with a tester 20.

As the test cell 90 is essentially a modular system, additional functions may be provided by adding additional modules. For example, one or more probe card analyzers 82 such as the ProbeWoRx® 300/200 mentioned above may be provided to inspect the probe cards 52 to ensure its proper functioning and to identify damage or wear. Further, an optical inspection system 83 such as a wafer Worx® or NSX® optical inspection system, both available from Rudolph Technologies, Inc. of Flanders, N.J. may be provided to perform high resolution optical inspection of probe marks made on the bond pads 24 of the wafers W by the probes 12 of the probe cards 52. Note that FIG. 4 is schematic in nature and the actual arrangement of additional functional modules such as a probe card analyzer or an optical inspection system may organized in any useful arrangement. In one embodiment, the robot 76 maybe adapted to couple one or more of the probe card analyzers 82 or optical inspection systems 83 thereto. The various portions of a modular system such as that illustrated in FIG. 4 are controlled in a known manner by a processor or controller often referred to as a cluster controller (not shown). A suitable cluster controller may be a computer mounted in any one of the modular components that make up the test cell 90, but is often found in the handler 76. The cluster controller may also be located remotely from the test cell 90. In addition to performing pre-programmed inspection and testing of a wafer or wafers, a cluster controller associated with a test cell 90 may modify testing and inspection of wafers W based on conditions that arise during testing or inspection. For example, where a cluster controller identifies defects on a wafer W or where a number of DUT's fail electrical tests, a predetermined testing and inspection recipe for the wafers W under test may be modified to exclude failed DUT's from further testing or inspection.

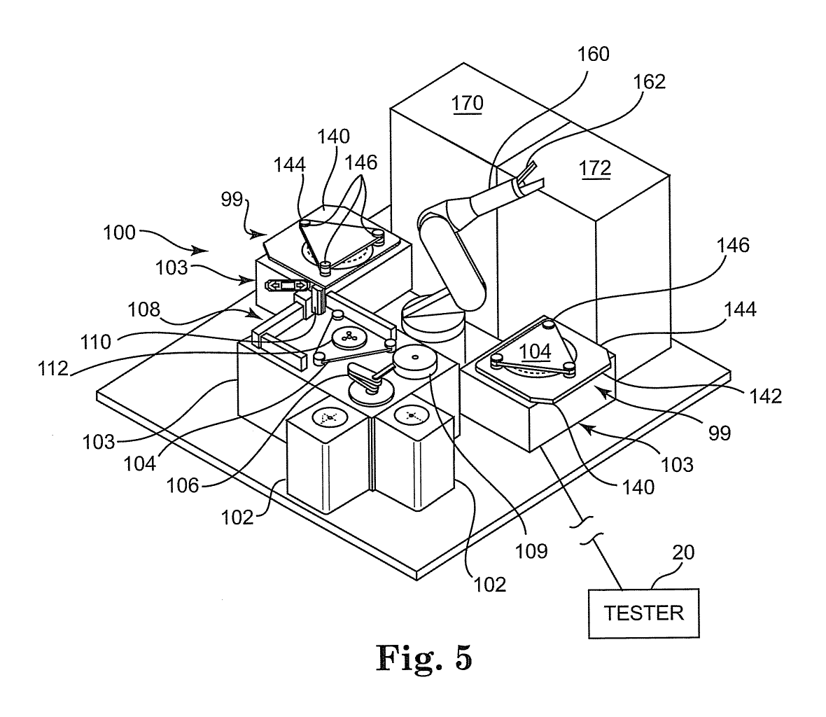

Turning now to FIG. 5, there is illustrated another embodiment of a test cell 100 according to the present invention. In this embodiment a test cell 100 includes a pair of FOUP's 102 for coupling wafer carriers (not shown) to the test cell 100. The FOUP's 102 are themselves coupled to a wafer handler 103 that may include one or more robots 106 for transport and manipulation of wafers W. The wafer handler 103 further includes an aligner 108 for determining an orientation of a wafer W and for correcting said orientation.

In one embodiment, the wafer aligner 108 may include and utilize a high-resolution optical system 110 to identify alignment features on the wafer in order to register the wafers to a wafer carrier 104. Additionally, the optical system 110 may be operable to conduct pre-probe wafer inspection, as well as post-probe wafer inspection, also known as wafer probe mark inspection. Alternatively, an additional pre-aligner 109 for determining a coarse orientation of a wafer W similar to that illustrated in FIG. 4 may be provided and one or more high resolution aligners 108 and optical inspection mechanisms may be coupled to the wafer handler 103 in a known manner, e.g. in a cluster configuration. In any case, an aligner 108 is adapted to receive a wafer carrier 104 on which a wafer W will be mounted.

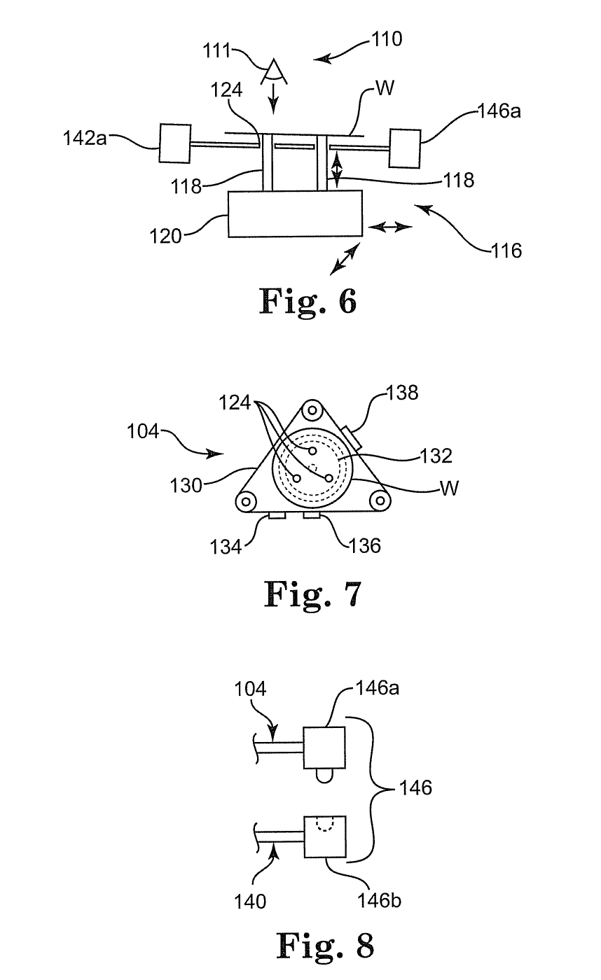

The wafer carrier 104 may incorporate a wafer chuck 112, which serves as a platform for the wafer W and that holds and facilitates correct positioning of the wafer W on the wafer carrier. The wafer carrier 104 further embodies alignment hardware 116 (FIG. 6), which allows reproducible positioning of the carrier in X, Y, and Z coordinates (as well as rotation) with respect to the wafer carrier 1 12. The alignment hardware 116 may function through kinematic or other suitable methods. As seen in FIG. 6, for example, the wafer W may be manipulated by means of a multi-point kinematic system 116 which is a combination of a kinematic system 118 and a transposable stage 120, or other suitable repeatable, precision docking, mounting, or positioning means. One embodiment of system 116 includes three or more vertically reciprocable lingers 122 mounted on stage 120. The fingers 122 extend through bores 124 in wafer carrier 104. The bores 124 are larger in diameter than fingers 122 to allow for translation of a wafer W supported on the fingers 122 with respect to the wafer carrier 104. In one embodiment the stage 120, in addition to being moveable in the X and Y directions, may also be rotatable about the Z axis which is normal to the wafer carrier 104. Alternatively, the wafer carrier 104 may be mounted on a rotation stage to permit rotation of the wafer W and wafer carrier 104 with respect to one another when the wafer W is supported on the fingers 122. Fingers 122 are reciprocable in the Z direction so as to lift a wafer W above the surface of the carrier 104 in an extended position, thereby allowing relative motion between the wafer carrier 104 and the kinematic system 116. Once the wafer W is in a desired position with respect to the wafer carrier 104, the fingers retract beneath the wafer carrier 104 so as to lower the wafer W onto the surface of the wafer carrier 104. In the retracted position, the fingers 122 are clear of the wafer carrier 104, which may be moved without striking the fingers 122.

In some embodiments the alignment process whereby a wafer W is aligned with respect to the carrier 104 is iterative. Where so provided, a pre-aligner 109 may perform a coarse alignment of the wafer so that the orientation of the wafer to the robot 106 is known to within a relatively coarse alignment. The wafer W is placed on the carrier 104 positioned adjacent aligner 108 for fine alignment. The wafer W is imaged by the camera 111 of system 110 and a second (a first alignment where pre-aligner 109 is not present) alignment is determined The kinematic system 116 is then activated to move the wafer W with respect to the wafer carrier 104 so as to bring the wafer W into fine alignment with the wafer carrier 104. In some instances the wafer W must be moved more than the clearance between fingers 118 and bores 124 allow, in these instances, the wafer W is set down on the wafer carrier 104 and the fingers 122 are repositioned to allow further relative motion between the wafer carrier 104 and the wafer W, i.e. the fingers 122 are moved relative to the wafer W before the wafer W is again supported upon the fingers 122. Further, it is noted that where a wafer carrier 104 utilizes a vacuum retention mechanism to secure a wafer W thereto, the act of securing the wafer W to the wafer carrier 104 may introduce a translation therebetween. Accordingly, in one embodiment a wafer W may be re-inspected for alignment after having been secured to a wafer carrier 104 to verify its alignment. As will be understood, depending on the nature of the wafer W and the specificity of the alignment desired, multiple alignments maybe necessary.

A wafer carrier 104 may be adapted in many ways to accomplish its intended purpose, which is to register a wafer W with a probe card for testing purposes. However, the wafer carrier 104 must have some means for securing a wafer W thereto and for registering the wafer W to a probe card. In one embodiment best viewed in FIG. 7, the wafer carrier has a central body 130 for supporting a wafer W. Note that in addition to a wafer W, the wafer carrier 104 may be adapted to support many different types of DUTs, including, but not limited to, singulated die and the like. The body 130 of a wafer carrier may be of any useful shape, which shape may depend on numerous factors such as space and size limitations, structural requirements, and compatibility with existing test equipment. The example of a triangular carrier 104 as depicted in the accompanying figures is provided for illustrative purposes only and is not intended to limit the scope of the invention in any manner. The wafer carrier 104 may be provided in alternative configurations such as, circular, square, or asymmetrical configurations.

The body 130 of the carrier 104 may include as described above, bores 124 for facilitating alignment of wafers W thereon. Further, body 130 maybe provided with a vacuum retention mechanism 132. The wafer carrier 104 may also employ power connections 134, identification hardware such as an RFID or a tag of some sort (not shown), vacuum connections 136, high structural rigidity or stiffness, and heat transfer or thermal control features and characteristics such as those know in the art for thermal or hot chucks (not shown). Furthermore, the wafer carrier 104 may employ a means to facilitate handling and transport, e.g. a gripping point 138 adapted to be gripped by a manipulator.

The wafer carrier 104, together with a probe card carrier 140, facilitate the testing of one or more DUT's on a wafer W without need for a traditional prober. This is accomplished by taking advantage of the fact that a wafer W may be addressed directly to a probe card by the wafer carrier 104. A probe card carrier 140, taken together with a probe card 142 secured thereto forms a test head 144. The probe card carrier 140 and the wafer carrier 104 each have complementary mechanical registration mechanisms 146 that ensure accurate and repeatable registration of the wafer W to the probe card 142. Taken together, a wafer carrier 104 and a probe card carrier 140 form a wafer pod 99. A wafer pod 99 may be relatively stationary, as where the probe card carrier 140, once a probe card 142 is mounted thereon, is positioned in a single location whereafter successive wafer carriers 104 are coupled thereto. In other embodiments, a wafer pod 99 may, once formed, be moved between various test cells for appropriate testing. For example, in one embodiment, a wafer pod 99 is formed and placed in a test cell where both electrical tests and burn-in processes are carried out. In another embodiment, a wafer pod 99 is moved between separate test cells (not shown) wherein electrical tests are carried out in a first test cell and burn-in processes are carried out in a separate test cell. Note that the aforementioned test cells may differ from that illustrated in the accompanying figures without exceeding the scope of the present invention. Further, it is to be understood that different test cells may be maintained at different temperatures for different types of testing or burn-in procedures as will be understood by those skilled in the art.

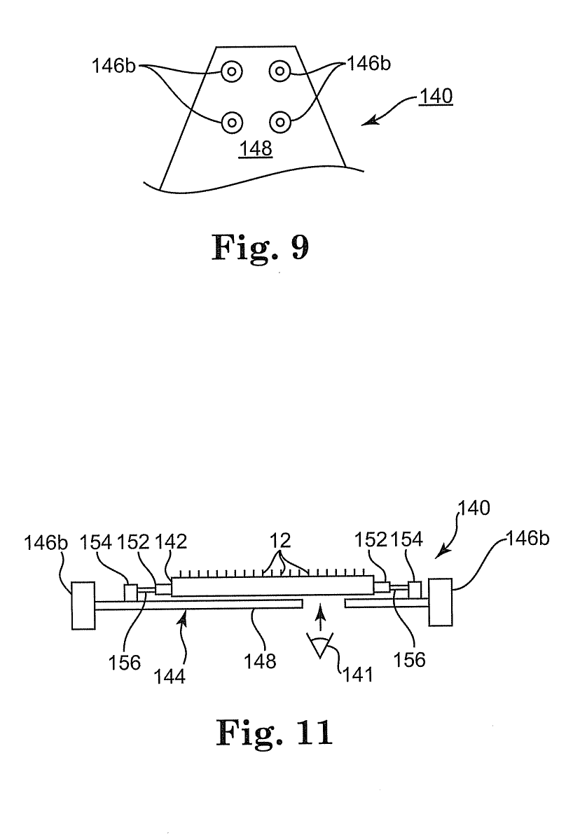

In the embodiment illustrated in FIG. 8, wafer carrier 104 is provided with a male portion 146a of registration mechanism 146 and probe card carrier 140 is provided with a female portion 146b of the mechanism. As will be appreciated, the male and female portions 146a,b provide accurate and repeatable registration of the carriers 104, 140, the one to the other without recourse to time consuming alignment procedures that might otherwise be required. While a male/female type of mechanism 146 is illustrated, those skilled in the art will readily appreciate that other types of positive registration mechanisms maybe utilized. As seen in FIG. 9, a probe card carrier 140 may be provided with multiple female portions 146b of registration mechanism 146 to provide accurate registration between a probe card and multiple portions of a wafer W. The relative positions of the female portions 146b illustrated in FIG. 9 may each be located so as to address the probe card 142 to a selected group of DUT's in a multi-touch test process. Note that the position of the female portions 146b in FIG. 9 will be determined based on the nature of the DUT's and may accordingly be different for each type of DUT being tested.

A large amount of force may be needed to properly seat the probes 12 into the bond pads 24. In one embodiment, registration mechanisms 146 may be provided with a locking means such as a camming mechanism, a vacuum assist mechanism, a threaded locking device or the like to draw the portions 146a,b together when the carriers are coupled to one another. Where the carriers 104 and 140 are both planar, even clamping forces applied by each of the registration mechanisms 146 will evenly drive the probes 12 into the bond pads 24. In some instances it may be desirable to introduce a slight curvature to the probe card 142 and/or its carrier 140 or the wafer chuck 112. This curvature may allow greater force to be applied between the probes 12 and bond pads 24 at the location of the curvature. Care should be taken to ensure that the selected curvature or lack of curvature will achieve the appropriate force between the probes 12 and the bond pads 24. In another embodiment, the registration mechanisms 146 serve only to register the carriers, the one to the other, and a press is a suitable sort is provided at the station 164 to force the carriers, and hence the wafer and the probe card into contact with one another.

Like the wafer carrier 104, the probe card carrier 140 has a central body 148 sized to mount a probe card 142 thereon. The size, shape and complexity of the central body 148 may vary based on the size of the probe card 142 to be mounted thereon. Note that because the force that must be applied between the probe card 142 and the wafer W may be high (on the order of 200-300 pounds), the central body of the probe card carrier 148 may be fashioned of a solid metal plate of sufficient strength, may be a ribbed casting, a fiber reinforced resin casting or any other suitable structure capable of handling the requisite forces and the temperature variations to which testing equipment is routinely subjected.

The central body 148 is also provided with one or more retention mechanisms 150 for securing a probe card 142 to the carrier 140. In one embodiment the retention mechanisms include a first block 152 attached to a probe card 142 and a second block 154 attached to the central body 148 of the probe card carrier 140. The blocks 152 and 154 are threaded to receive a threaded adjustment pin 156 that may be rotated to adjust the distance between the blocks 152, 154. The pins 156 maybe rotated manually or by means of a rotary actuator (not shown). Further, one or more encoders or position indicators (not shown) may be mounted between the probe card 142 and the central body 148 to show the relative location of the probe card 142 with respect to the carrier 140 at any given time. In this way, location information may be generated for the probe card 142 to ensure that it is aligned with a wafer W. Retention mechanisms may also be provided with height modification functionality to adjust the planarity of the probe card 142 with respect to its carrier 140. A threaded adjustment screw mechanism may be used to provide the requisite planarity adjustment. Position height sensors (not shown) mounted on the carrier 140 may provide height information for use in modifying the planarity of the probe card 142. A suitable position height sensor is a capacitative height sensor.

A signal delivery system 16 is provided to couple a probe card 142 secured to a carrier 140 to a tester 20. Additional mechanical, pneumatic, and electrical systems may further be coupled to the carrier 140 as needed.

As seen in FIG. 5, a manipulator is adapted to move carriers 104 and 140 to their necessary locations. The manipulator 160 is in one embodiment a multi axis robot and has a gripper 162 at its distal end. The gripper 162 illustrated in FIG. 5 is a simple, two jaw gripping in which the jaws clamp a carrier 104 or 140 therebetween. Preferably the gripper 162 will grasp or engage the carriers 104 or 140 only at a designated location, though it is to be understood that gripper may grasp a carrier in any useful location. In another embodiment the gripper 162 may form a male or female portion of a coupling that includes not only mechanical coupling means, but also electrical and pneumatic coupling means as well. In this embodiment, vacuum pressure may be provided to a carrier through the coupling as the manipulator 160 moves the carrier to its intended position. Similarly, electrical signals may be routed through the manipulator 160 to assist in identifying the wafer or probe card and to send safety and/or functional feedback to a controller (not shown). In another embodiment, the wafer carriers 104 may be moved via a track or conveyor system (not shown) between a loading station and a test station.

As described above in conjunction with FIG. 6, an imaging device or camera may be provided for aligning a probe card 142 to its carrier 140. This camera may be separate from the carrier 140, as for example where a camera of aligner 108 is utilized to align the probe card to its carrier 140. Note that once a probe card 140 is aligned to its carrier, this alignment will not be needed again or at the very least will not be needed until after a pre-determined number of testing cycles or until it is determined that there is a problem with the probe card 142. In another embodiment, an independently mounted camera not associated with the aligner 108 may be addressed to a probe card 142 on a carrier 140 to ensure that the two are registered to one another. This independent camera may be part of a probe card analysis system. Further, where a probe card 142 is provided with alignment marks or reticles on its backside, a simple camera 141 (FIG. 11) may be mounted directly on or in the central body 148 of the carrier 140 to ensure that the probe card is properly aligned thereto.

In some embodiments, a probe card alignment jig (not shown) that is separate from the probe card carrier 140 may be provided to align a probe card to a tester frame or probe card carrier. The probe card alignment jig may employ an optical system and suitable tooling to allow registration points to be positioned with suitable accuracy.

The test cell 100 may be provided with one, two or more stations 103 in which a probe card carrier 140 may be positioned for electrical testing of wafers W. Further, such stations may be vertically stacked or oriented on edge to increase the density and throughput of a test cell 100.

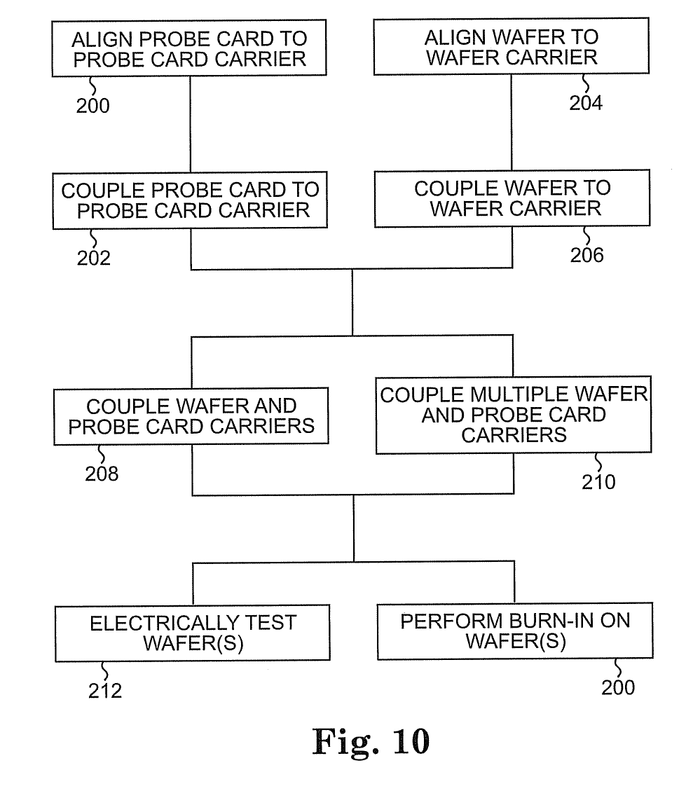

FIG. 10 illustrates an exemplary embodiment of the present invention. In its simplest form, the process of testing a wafer using a test cell arranged according to the principles of the present invention involves aligning (200) and coupling (202) a probe card to a probe card carrier. Similarly, a wafer is aligned (204) and coupled (206) to a wafer carrier. This can be carried out simultaneously or in a temporally separated manner. In one embodiment a probe card is aligned and coupled to its carrier and then a succession of wafer are aligned and coupled to one or more carriers.

Once the respective carriers each have a probe card or wafer aligned and coupled thereto, the respective carriers are coupled to one another in a registered manner (208). In addition to coupling a single pair or carriers to one another, where a test cell is adapted to handle multiple probe cards on multiple probe card carriers, multiple probe card carriers maybe coupled to multiple wafer carriers (210).

A wafer pod that includes a wafer carrier and a probe card carrier may then be electrically tested (212) and/or have a burn-in test performed thereon (214). Note that for a given wafer in a wafer pod, electrical test 212 generally comes before the burn-in test 214. However, where multiple wafer pods are being processed simultaneously, electrical test 212 and burn-in test 214 may take simultaneously on separate wafer pods.

In another embodiment, preparation of the test cell 100 for use involves mounting a probe card 142 having a design that is complementary to that of the wafers W to be tested to a carrier 140 that is similarly complimentary to the design of the wafer carrier 104 that holds the wafer W to be tested. The carrier 140 and probe card 142 may be adapted for one or multiple touch electrical testing as described above. In one embodiment, the probe card 142 is secured to its carrier 140 by means of retention mechanisms 150 in a probes-up orientation. This orientation is sometimes referred to as the “dead bug” orientation for obvious reasons In another embodiment, the probe card 142 and its carrier will be adapted for a more traditional, “live bug” orientation wherein the probes are oriented in a downward orientation.

Once the probe card 142 is secured to its earner 140, sensors mounted on the earner 140 or the sensors of a probe card analysis system are used to measure alignment and planarity, among other charactenstics, of the probe card 142 These characteristics are adjusted using the retention mechanisms 150 or the like to obtain an alignment that is within a user defined range of acceptable alignments The alignment of the probe card 142 to its carrier 140 is noted and retained for future reference in aligning wafers W thereto Once the probe card 142 is aligned to its carrier 140, the manipulator 160 uses its gripper 162 to grasp the earner 142 and move it to one of stations 164 This move presumes that the probe card 142 is not attached to its carrier 140 directly in one of the stations 164 As will be appreciated, multiple probe cards 142 may be arranged in this manner to increase the utilization of the test cell 90. The probe card 142 is now ready for testing and may be heated or cooled to a pre-determined temperature or maintained at ambient temperatures.

Wafers W are then readied for test A wafer W is obtained from a FOUP 75 by robot 78 of handler 76 and provided to a pre-aligner for coarse alignment A pre-aligner may be of the relatively simple type illustrated in FIG. 2 or of the higher resolution type 108 illustrated in FIG. 5 In the embodiment illustrated in FIG. 5, a high resolution aligner 108 is used to image a wafer to identify features thereon Using the relative location of these features, the aligner 108 instructs the multi-point kinematic system 116 to properly align the wafer W The aligner 108 may align the wafer W in a single step or may do so iteratively Once the wafer W is aligned, the wafer W is secured to the wafer chuck 112 using a vacuum retention system In one embodiment, the aligner 108 will check the alignment of the wafer W once it has been secured to the wafer chuck 112 to ensure that it did not become misaligned as it was secured to the chuck.

Once the wafer W is secured to its carrier 104, the manipulator 160 moves the wafer earner 104 to the station where the probe card earner 140 is located As the probe card 142 is in the embodiment illustrated in FIG. 5 in a dead bug orientation, the wafer carrier 104 is inverted and the registration mechanisms 146 of the two carriers 104, 140 are coupled to one another to address the bond pads 24 of the wafer W to the probes 12 of the probe card. The wafer W and the probe card 142 are then pressed together using a press or by activating a locking mechanism of the registration mechanism 146. The coupled carriers are maintained in this arrangement for the duration of the electrical test.

The embodiment illustrated in FIG. 5 has the combined carriers 104, 140 in a horizontal orientation. In one example, the wafer and probe pins may be oriented in the conventional manner, that is to say, wafer bonding pads facing up and probe pins facing down. In another example, the probe pins may be facing up and the bonding pads down. In a further example, a vertical orientation may be employed.

As is alluded to above, beyond the electrical test that is carried out by the test cell 90, additional testing may be carried out on the probe cards and wafers, not only to ensure that these items remain undamaged, but also to track the operation of the test cell 90 itself. For example, optical inspection of a wafer both before and after electrical test may reveal faults in the operation of a test cell 90 that may lead to defects in a wafer. Optical 2D and 3D inspection of bond pads may identify improper application of probe pins to the bond pads on an individual or global basis. That is to say, if there are problems with a single probe pin, the resultant defects may be identified by optical inspection. Similarly, metrology and inspection of the probe marks may also reveal issues such as lack of planarity, errors in the spacing of probe pins, thermal expansion issues, and mis-alignment of the probe card to the wafer. While in a minimal embodiment the test cell 90 may include only wafer carriers, probe card carriers, a minimal alignment system and a connection to a tester, more complete and useful test cells 90 will include one or more high resolution optical inspection systems for inspection and metrology of probe marks formed on bond pads and probe card analysis tools to identify and correct issues with the probe cards.

Note that a test cell is preferably formed as an integrated cluster of the aforementioned components. Alternatively, the contemplated test cell may be networked or otherwise linked to remote back end test equipment. The fully integrated test cell, while more efficient may not be sufficiently efficient to warrant the retirement of existing equipment. Accordingly, users of a test cell and any associated cluster controllers or fab monitoring systems should take into account the need to schedule the transport of wafers and/or probe card (with our without the attached probe card carrier) to remotely located inspection or analysis equipment. According to certain aspects of the invention, employing such functionality may provide wafer fabricators with a tool for overall wafer yield management via a closed-loop metrology and analysis.

It is preferred to provide folly modular components for use in a test cell. For example, wafer carriers should be capable of mounting both 200 and 300 mm wafers as well as other sizes and shapes of semiconductor substrates and carrying mechanisms. The greater variability between probe cards, which are after all, unique for each semiconductor product, militates for the adoption of a universal or modular approach in connecting probe cards 142 to a carrier 140. In this manner, a single type of carrier can be used for multiple types of probe cards. Further, as the adoption of the present invention in its many forms grows, additional tools or systems may adopt the modular aspect of the carriers to enhance the functionality thereof. To expand on the concept of optical inspection discussed above, an optical inspection system 170 may be provided with a stage adapted to mount a wafer carrier thereto. Similarly, a probe card analysis system or a bond pad inspection system 172 may be included. Accordingly, a manipulator 160 may be used to place a wafer (still on its carrier) in an inspection system 170 for optical inspection or to place a probe card carrier with a probe card thereon into a probe card analysis system or a bond pad inspection system 172.

As will be appreciated, certain of the described embodiments of said semiconductor test system may further comprise wafer analysis software modules that provide scrub to pad correlation analysis; tester to wafer parallelism; fixture deflection, wafer carrier accuracy and performance under load; test at temperature analysis; wafer lot analysis; fixture spring rate analysis; pre qualification and analysis of wafer test cell; process limit analysis; wafer bond pad punch through analysis; wafer scrub depth analysis; defect inspection; and/or bump height.

In certain other embodiments of the present invention, a wafer pod, as described above, can be configured such that, either simultaneously or sequentially, the wafer pod is operable to proceed from wafer test directly to full wafer burn-in. In this embodiment the wafer pod is not separated throughout the wafer testing and burn in process. This results in fewer touchdowns, less wafer damage, and greater reliability.

### CONCLUSION

Although specific embodiments of the present invention have been illustrated and described herein, it will be appreciated by those of ordinary skill in the art that any arrangement that is calculated to achieve the same purpose may be substituted for the specific embodiments shown. Many adaptations of the invention will be apparent to those of ordinary skill in the art. Accordingly, this application is intended to cover any adaptations or variations of the invention. It is manifestly intended that this invention be limited only by the following claims and equivalents thereof.

What is claimed is:

1. A semiconductor electrical test system comprising:
a wafer carrier having a retaining mechanism for retaining a wafer thereto in a desired orientation with respect to the wafer carrier and a first registration mechanism;
a probe card carrier having a probe card secured thereto in a desired orientation with respect to the probe card carrier and a second registration mechanism;
the first and the second registration mechanism being complementary with one another to spatially register the wafer to the probe card.

2. The semiconductor electrical test system of claim 1 further comprising a means for applying force between the probe card and the wafer selected from a group consisting of a press and a locking mechanism of the registration mechanism.

3. A semiconductor test system comprising:
a wafer carrier;
a probe card carrier, the wafer carrier and probe card carrier being registrable, the one with the other, in a predetermined spatial relationship an aligner having a camera for capturing alignment data;
a wafer handler having at least one FOUP and one robot; and, a manipulator with a gripper adapted to grip the wafer carrier and the probe card carrier.

4. The semiconductor test system of claim 3 wherein the aligner has a camera for capturing alignment information concerning the alignment of the wafer with respect to the wafer carrier.

5. The semiconductor test system of claim 3 wherein the aligner comprises a kinematic alignment stage adapted to selectively address a wafer placed on the wafer carrier, the kinematic alignment stage being moveable with respect to the wafer stage.

6. The semiconductor test system of claim 3 wherein the probe card carrier further comprises at least one electrical connector that provides electrical connection between a probe card secured to the probe card carrier and an electrical tester.

7. The semiconductor test system of claim 4 wherein the aligner has a camera and an optical system of sufficient resolution to capture an image of a bond pad useful for analyzing the performance of a probe card.

8. The semiconductor test system of claim 3 wherein the wafer carrier comprises a central body having a registration mechanism for registering the wafer carrier to the probe card carrier attached thereto, the registration mechanism of the wafer carrier being complementary to the registration mechanism of the probe card carrier, the central body of the wafer carrier having a wafer retention mechanism for securing a wafer to the wafer carrier.

9. The semiconductor test system of claim 3 further comprising a probe card analyzing system positioned such that the manipulator may move the probe card carrier between a first position in which the probe card carrier may be registered to a wafer carrier and a second position wherein the probe card analyzing system may inspect a probe card mounted on the probe card carrier.

10. The semiconductor test system of claim 3 wherein the manipulator inverts one of the probe card carrier and the wafer carrier to register the probe card carrier to the wafer carrier, the registration being such that at least one bond pad of a wafer secured to the wafer carrier is addressed to a probe of a probe card secured to the probe card carrier.

11. A method of manufacturing a semiconductor device comprising:
providing a wafer carrier and a probe card carrier, the wafer and probe card carriers comprising mechanisms for mechanically aligning the one to the other;
mounting a probe card on the probe card carrier in a known orientation with respect to the probe card carrier;
mounting a wafer on the wafer carrier in a known orientation with respect to the wafer carrier;
addressing the alignment mechanisms of the wafer and probe card carriers to one another so as to address the probe card to the wafer; and,
electrically testing at least one semiconductor device formed on the wafer to verify whether the at least one semiconductor device functions according to a user-defined set of criteria.

12. The method of manufacturing a semiconductor device of claim 10 further comprising:
providing a probe card analysis system having an interface with a mechanical alignment mechanism; and,
addressing the alignment mechanism of the probe card carrier to the alignment mechanism of the probe card analysis system on a periodic, user-defined schedule.

13. An electrical test system for semiconductor devices comprising:
a closeable cassette having a first portion and a second portion, the first and second portions being provided with a registration mechanism such that when the first and second portions of the cassette are addressed to one another, the first and second portions of the cassette are in a known spatial registration with respect to one another;
a wafer support coupled to the first portion of the cassette for supporting a wafer;
an alignment mechanism comprising an imager for capturing optical alignment data of the wafer and an alignment stage for selectively moving a wafer with respect to wafer support based at least in part on the alignment data captured by the imager;
a probe card coupled to the second portion of the cassette for electrically testing a wafer, the probe card being coupled to the second portion in a known position with respect to the second portion of the cassette; and,
a support mechanism upon which the cassette may be supported when the cassette is in a closed position, the support mechanism comprising at least an electrical connector to electrically couple a probe card secured to the second portion of the cassette to an electrical tester.

14. The electrical test system for semiconductor devices of claim 13 further comprising a manipulator adapted to grasp a closed cassette and move it from a location where the cassette may be loaded and unloaded, to the support mechanism, where a wafer in the cassette may be electrically tested.

15. A method of electrically testing a semiconductor device comprising:
providing a closable cassette having a first portion adapted to secure thereto a probe card and a second portion adapted to secure thereto a semiconductor device, the first and second portions being further provided with a registration mechanism for spatially registering the first and second portions, the one to the other;
securing a probe card to the first portion of the cassette in a known orientation thereto;
securing a semiconductor device to the second portion of the cassette in a known orientation thereto;
closing the cassette such that at least one probe pin of the probe card is addressed to a bond pad of the semiconductor device, the known orientations of the probe card and semiconductor device to their respective portions of the cassette being such that the registration mechanism of the cassette ensures that the at least one probe pin of the probe card is addressed to a bond pad of the semiconductor device;
coupling the at least one probe pin of the probe card to an electrical tester; and,
activating the electrical tester to electrically test the semiconductor device.

16. The method of electrically testing a semiconductor device of claim 15 further comprising:
optically inspecting the bond pads of the semiconductor device after the electrical test is complete.

17. A method of electrically testing a semiconductor device comprising:
aligning a wafer to a wafer carrier and securing the wafer to the wafer carrier;
aligning a probe card to a probe card carrier and securing the probe card to the probe card carrier;
addressing the wafer carrier to the probe card carrier such that one or more probe pins on the probe card contact one or more probe pads on the wafer, the addressing of the wafer carrier to the probe card carrier being carried out with requiring alignment of the one to the other.
